(19) United States
(12) Patent Application Publication
(10) Pub. No.: US 2023/0343796 A1
(43) Pub. Date: Oct. 26, 2023

(54) PIN BINDING STRUCTURE, ARRAY SUBSTRATE AND DISPLAY PANEL

(71) Applicant: Hefei Visionox Technology Co., Ltd., Hefei (CN)

(72) Inventors: Cai ZHENG, Hefei (CN); Liwei DING, Hefei (CN); Yihong MA, Hefei (CN); Hongjun XIE, Hefei (CN)

(73) Assignee: Hefei Visionox Technology Co., Ltd., Hefei (CN)

(21) Appl. No.: 18/342,074

(22) Filed: Jun. 27, 2023

Related U.S. Application Data
(63) Continuation of application No. PCT/CN2022/071082, filed on Jan. 10, 2022.

(30) Foreign Application Priority Data
Jun. 17, 2021 (CN) 202110673792.9

(51) Int. Cl. H01L 27/12

(52) U.S. Cl. CPC H01L 27/124

(57) ABSTRACT

A pin binding structure, an array substrate and a display panel. The pin binding structure comprises: a first pin group, comprising a plurality of first pins distributed at intervals in a first direction, the first pin being in a bent line structure having a first opening, and the first openings of the plurality of first pins in the first pin group having the same orientation; and a second pin group, comprising a plurality of second pins distributed at intervals in the first direction, the second pin being in a bent line structure having a second opening, the second openings of the plurality of second pins in the second pin group having the same orientation, and the orientation of the second openings of the second pins being the opposite of the orientation of the first openings of the first pins.

### CROSS REFERENCE

The present disclosure is a continuation of International Application No. PCT/CN2022/071082, filed on Jan. 10, 2022, which claims priority to Chinese Patent Application No. 202110673792.9, filed on Jun. 17, 2021, titled “Pin Binding Structure, Array Substrate, and Display Panel”, both of which are hereby incorporated by reference in their entireties.

### TECHNICAL FIELD

The present disclosure relates to the field of display technology, in particular to a pin binding structure, an array substrate and a display panel.

### BACKGROUND

With an improvement of users' requirements on performance of display products, display products continue to develop in a direction of high refresh rate and high resolution, resulting in more and more wiring lines, which requires that more binding pins need to be left when display products are designed. However, a binding pin form and layout scheme adopted by traditional display products can no longer meet needs of display products with high refresh rate and high resolution.

### SUMMARY

Embodiments of the present disclosure provide a pin binding structure, an array substrate, and a display panel, which can meet a high refresh rate and high resolution requirements of a display panel.

In a first aspect, an embodiment of the present disclosure provides a pin binding structure, comprising: at least one first pin group, wherein the first pin group comprises a plurality of first pins distributed at intervals along a first direction, each first pin is in a bent line structure with a first opening, and first openings of the plurality of first pins in the first pin group have the same orientation; at least one second pin group, wherein each second pin group comprises a plurality of second pins distributed at intervals along the first direction, each second pin is formed in a bent line structure with a second opening, second openings of the plurality of second pins in the second pin group have the same orientation, and the orientation of the second openings of the second pins is opposite to the orientation of the first openings of the first pins, wherein the first pin group and the second pin group are distributed along a second direction, and the plurality of first pins and the plurality of second pins respectively in the first pin group and the second pin group that are adjacent are at least partially distributed in a comb-tooth-shaped insertion manner.

In a second aspect, an embodiment of the present disclosure provides an array substrate, comprising a first area and a second area, wherein the second area is distributed around the first area, the second area comprises a binding area provided with a plurality of pins adopting the pin binding structure according to any one of the above embodiments.

In a third aspect, an embodiment of the present disclosure provides a display panel comprising the array substrate according to any one of the above embodiments.

Embodiments of the present disclosure provide the pin binding structure, the array substrate, and the display panel. The pin binding structure includes the first pin group and the second pin group, and the first pin group and the second pin group are alternately distributed along the second direction. Each first pin of the first pin group is formed in a bent line structure with the first opening. Each second pin of the second pin group is formed in a bent line structure with the second opening. The pins in the bent line structure can better adapt to an irregular binding space. The pins in the adjacent pin groups are arranged in a comb-tooth-shaped insertion manner. When the distance in the second direction is constant, more pins can be arranged in the binding space. In addition, there is a certain reserved space between the pin group in the first row and the pin group in the last row, which can be used for wiring lines, etc. Therefore, the pin binding structure can meet needs of display panels with high refresh rate and high resolution performance.

### BRIEF DESCRIPTION OF THE DRAWINGS

FIG. 1 is a schematic structural diagram of a pin binding structure provided by an embodiment of the present disclosure;

FIG. 2 is a schematic structural diagram of a pin binding structure provided by another embodiment of the present disclosure;

FIG. 3 is a schematic structural diagram of a first pin group of a pin binding structure provided by an embodiment of the present disclosure;

FIG. 4 is another structural schematic diagram of a first pin group of a pin binding structure provided by an embodiment of the present disclosure;

FIG. 5 is another structural schematic diagram of a first pin group of a pin binding structure provided by an embodiment of the present disclosure;

FIG. 6 is a schematic structural diagram of a second pin group of a pin binding structure provided by an embodiment of the present disclosure;

FIG. 7 is a schematic structural diagram of a pin binding structure provided by another embodiment of the present disclosure;

FIG. 8 is a schematic structural diagram of a pin binding structure provided by another embodiment of the present disclosure;

FIG. 9 is a schematic structural diagram of a pin binding structure provided in another embodiment of the present disclosure; and

FIG. 10 is a schematic structural diagram of an array substrate further provided in an embodiment of the present disclosure.

### DETAILED DESCRIPTION

With an improvement of users' requirements on performance of display products, display products continue to develop in a direction of high refresh rate and high resolution, resulting in more and more wiring lines, which requires that more binding pins need to be left when display products are designed. However, a binding pin form and layout scheme adopted by traditional display products can no longer meet needs of display products with high refresh rate and high resolution.

In order to solve the above problem, embodiments of the present disclosure provide a pin binding structure, an array substrate and a display panel. Various embodiments of the pin binding structure, the array substrate and the display panel will be explained referring to accompanying FIGS. 1 to 10 below.

Referring to FIG. 1 to FIG. 9, the pin binding structure provided by an embodiment of the present disclosure includes at least one first pin group 100 and at least one second pin group 200.

Each first pin group 100 includes a plurality of first pins 110 distributed at intervals along a first direction X. Each first pin 110 is formed in a bent line structure with a first opening. First openings of the plurality of first pins 110 in the first pin group 100 have the same orientation.

Each second pin group 200 includes a plurality of second pins 210 distributed at intervals along the first direction X. Each second pin 210 is formed in a bent line structure with a second opening. Second openings of the plurality of second pins 210 in the second pin group 200 have the same orientation. The orientation of the second openings of the second pins 210 is opposite to the orientation of the first openings of the first pins 110.

Both the first pins 110 and the second pins 210 are arranged in a bent line structure, and their opening orientations are opposite, so that a large number of pins can also be arranged in an irregular space.

The first pin group 100 and the second pin group 200 are distributed along a second direction Y. The plurality of first pins 110 and the plurality of second pins 210 respectively in the first pin group 100 and the second pin group 200 that are adjacent are at least partially arranged in a comb-tooth-shaped insertion manner.

The plurality of first pins 110 and the plurality of second pins 210 respectively in the first pin group 100 and the second pin group 200 that are adjacent may be partially arranged in a comb-tooth-shaped insertion manner, or all of them are arranged in a comb-tooth-shaped insertion manner.

The first direction X and the second direction Y may intersect at any preset angle. Optionally, an angle between the first direction X and the second direction Y may be 90 degrees, that is, the second direction Y is perpendicular to the first direction X.

In the present disclosure, the number of pins in each pin group, the size of the pins, and the size of the openings can all be adaptively adjusted according to the size and shape of a binding area.

At least one first pin group 100 can include at least two first pin groups 100. At least one second pin group 200 can include at least two second pin groups 200. At least two first pin groups 100 and at least two second pin groups 200 are alternately distributed along the second direction Y. The first pins 110 and the second pins 210 respectively in adjacent groups of the at least two first pin groups 100 and the at least two second pin groups 200 are at least partially arranged in a comb-tooth-shaped insertion manner. In the case of the distance in the second direction Y is constant, more pins can be arranged in the binding space. In addition, there is a certain reserved space between the pin group in the first row and the pin group in the last row, which can be used for wiring lines, etc. Therefore, the pin binding structure provided by the embodiment of the present disclosure can meet requirements of a display panel with high refresh rate and high resolution performance.

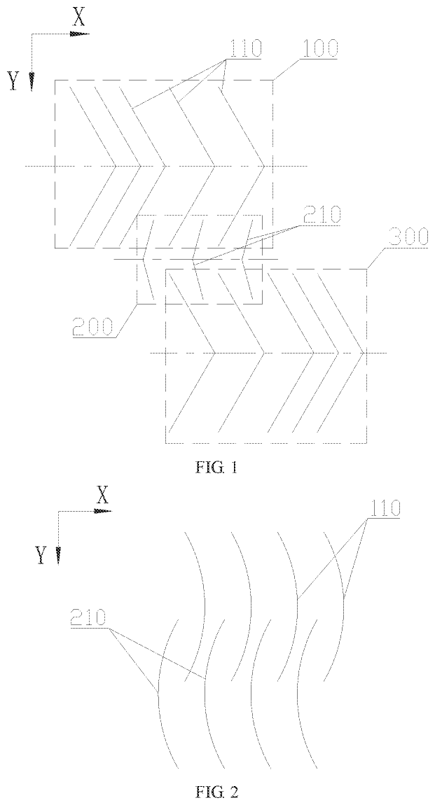

Referring to FIG. 1 and FIG. 2, the first pin 110 and the second pin 210 are in a bent line structure, and the bent line structure can be a straight line bent structure or an arc bent structure.

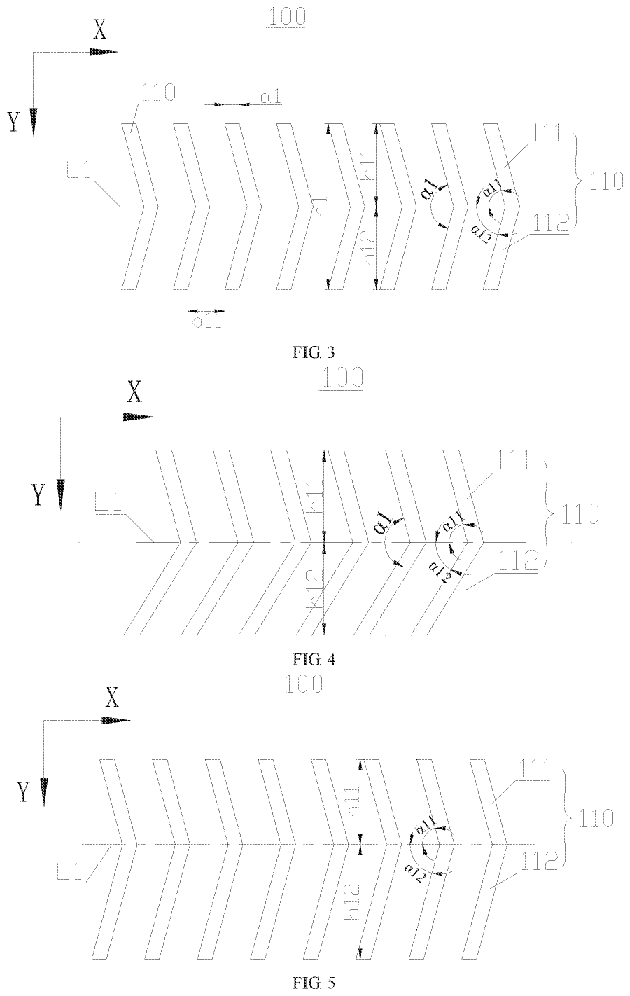

Referring to FIG. 3 to FIG. 5, the first pins 110 in the first pin group 100 may be arranged at equal intervals in the first direction X.

In order to prevent short circuit during binding, a minimum distance b11 between two adjacent first pins 110 in the first pin group 100 in the first direction X is greater than or equal to 6 μm.

A width a1 of the first pin 110 in the first direction X may be greater than or equal to 8 μm to ensure a binding effect.

In some optional embodiments, the first pin 110 may include a first portion 111 and a second portion 112 arranged in sequence in the second direction Y and connected at a first predetermined angle α1. The first predetermined angle α1 is ranged from 0° to 180°. A connection angle between the first portion 111 and the second portion 112 of the first pin 110 may be 60°, 90°, or 150°.

The first pin group 100 may have a first fold line L1 extending along the first direction X, and the first portion 111 and the second portion 112 of the first pin 110 are located on two sides of the first fold line L1 respectively. The present disclosure does not specifically limit the size of the first portion 111 and the second portion 112 and their degree of inclination relative to the first fold line L1.

In some optional embodiments, as shown in FIG. 3, the first portion 111 and the second portion 112 of the first pin 110 can be symmetrically arranged with the first fold line L1 as an axis of symmetry. Then, an angle α11 between the first portion 111 of the first pin 110 and the first fold line L1 is equal to an angle α12 between the second portion 112 and the first fold line L1. Meanwhile, a size h11 of the first portion 111 in the second direction Y can be equal to a size h12 of the second portion 112 in the second direction Y. α1=α11+α12, h1=h11+h12, wherein h1 represents the size of the first pin 110 in the second direction Y.

In other optional embodiments, as shown in FIG. 4, the angle α11 between the first portion 111 of the first pin 110 and the first fold line L1 may not be equal to the angle α12 between the second portion 112 and the first fold line L1.

As shown in FIG. 5, the size h11 of the first portion 111 in the second direction Y and the size h12 of the second portion 112 in the second direction Y may also be different.

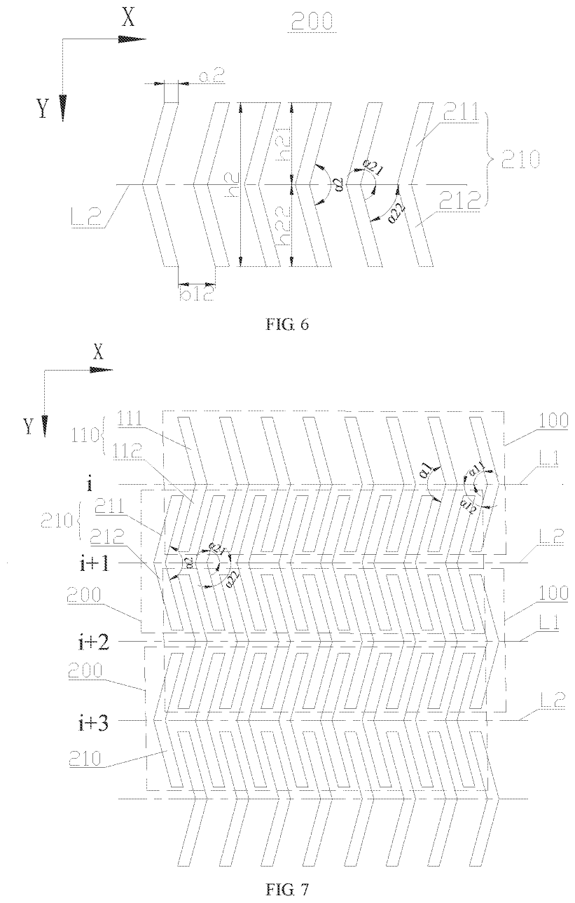

Referring to FIG. 6, the second pins 210 in the second pin group 200 may be arranged at equal intervals in the first direction X.

Optionally, in order to prevent short circuit during binding, a minimum distance b12 between two adjacent second pins 210 in the second pin group 200 in the first direction X is greater than or equal to 6 μm.

Optionally, a width a2 of the second pin 210 in the first direction X may be greater than or equal to 8 μm to ensure a binding effect.

In some optional embodiments, the second pin 210 may include a first connecting portion 211 and a second connecting portion 212 arranged in sequence in the second direction Y and connected at a second predetermined angle α2. The second predetermined angle α2 is ranged from 0° to 180°. Optionally, a connection angle between the first connecting portion 211 and the second connecting portion 212 of the second pin 210 may be 60°, 90°, or 150°.

The second pin group 200 may have a second fold line L2 along the first direction X, and the first connecting portion 211 and the second connecting portion 212 of the second pin 210 are respectively located on two sides of the second fold line L2. The present disclosure does not specifically limit the size of the first connecting portion 211 and the second connecting portion 212 of the second pin 210 and their degree of inclination relative to the second folding line L2.

In some optional embodiments, as shown in FIG. 6, the first connecting portion 211 and the second connecting portion 212 of the second pin 210 can be arranged symmetrically with the second folding line L2 as an axis of symmetry. Then, an angle α21 between the first connecting portion 211 of the second pin 210 and the second fold line L2 is equal to an angle α22 between the second connecting portion 212 and the second fold line L2. A size h21 of the first connecting portion 211 in the second direction Y can be equal to a size h22 of the connecting portion 212 in the second direction Y. α2=α21+α22, h2=h21+h22, wherein h2 represents the size of the second pin 210 in the second direction Y.

In other optional embodiments, the angle α21 between the first connecting portion 211 of the second pin 210 and the second fold line L2 may not be equal to the angle α22 between the second connecting portion 212 and the second fold line L2.

Optionally, the size h21 of the first connecting portion 211 of the second pin 210 in the second direction Y may be different from the size h22 of the second connecting portion 212 in the second direction Y.

The first predetermined angle α1 and the second predetermined angle α2 can be equal. That is, the connection angle between the first portion 111 and the second portion 112 of the first pin 110 is equal to that between the first connecting portion 211 and the second portion 212 of the second pin 210. The first predetermined angle α2 and the second predetermined angle α2 may also be different.

In some optional embodiments, the width a1 of the first pin 110 in the first direction X and the width a2 of the second pin 210 in the first direction X may be equal or not.

Referring to FIG. 7 and FIG. 8, in the pin binding structure provided by the embodiment of the present disclosure, the first connecting portions 211 of the second pins 210 in the second pin group 200 in the (i+1)-th row are parallel to the second portions 112 of the first pins 110 in the first pin group 100 in the i-th row. With this arrangement, more pins can be arranged in a binding space under the condition that the distance in the first direction X is constant. Wherein, i is defined as any integer greater than or equal to 1.

Optionally, the second connecting portions 212 of the second pins 210 in the second pin group 200 in the (i+1)-th row are parallel to the first portions 111 of the first pins 110 in the first pin group 100 in the (i+2)-th row, which can further increase an arrangement density of the pins. The pin binding structure includes at least three pin groups.

In some optional embodiments, the angle α12 between the second portion 112 of the first pin 110 and the first fold line L1 can be set to be equal to the angle α21 between the first connecting portion 211 of the second pin 210 and the second fold line L2. Thus the first connecting portions 211 of the second pins 210 of the second pin group 200 in the (i+1)-th row are parallel to the second connecting portions 112 of the first pins 110 of the first pin group 100 in the i-th row. In addition, the angle α11 between the first portions 111 of the first pins 110 and the first fold line L1 can be set to be equal to the angle α22 between the second connecting portions 212 of the second pins 210 and the second fold line L2, so that the second connecting portions 212 of the second pins 210 of the second pin group 200 in the (i+1)-th row are parallel to the first portions 111 of the first pins 110 of the first pin group 100 in the (i+2)-th row.

In some optional embodiments, the first connecting portions 211 of the second pins 210 in the second pin group 200 in the i-th row are connected to the second portions 112 of the first pins 110 in the first pin group 100 in the (i+1)-th row may have the same size, which can make a layout of the pins more compact.

Optionally, the second connecting portions 212 of the second pins 210 in the second pin group 200 in the (i+1)-th row and the first portions 111 of the first pins 110 in the first pin group 100 in the (i+2)-th row may have the same size.

Optionally, a shape and size of the first pins 110 with a shape and size of the second pins 210 can be the same.

It can be understood that, as shown in FIG. 8, in the pin binding structure provided by the embodiment of the present disclosure, there is a first distance D1 from the first fold line L1 of the first pin group 100 in the i-th row to the second fold line L2 of the second pin group 200 in the (i+1)-th row. There is a second distance D2 from the second fold line L2 of the second pin group 200 in the (i+1)-th row to the first fold line L1 of the first pin group 100 in the (i+2)-th row.

In some optional embodiments, the first distance D1 and the second distance D2 may be equal.

In some optional embodiments, the first distance D1 may be greater than both the size h12 of the second portions 112 of the first pins 110 in the i-th row in the second direction Y and the size h21 of the first connecting portions 211 of the second pins 210 in the i-th row in the second direction Y. Thus the plurality of first pins 110 of the first pin group 100 in the i-th row are spaced apart from the second fold line L2 of the second pin group 200 in the (i+1)-th row. The plurality of second pins 210 in the second pin group 200 in the (i+1)-th row are spaced apart from the first fold line L1 of the first pin group 100 in the i-th row.

In some optional embodiments, the first distance D2 may be greater than both the size h22 of the second connecting portions 212 of the second pins 210 in the (i+1)-th row in the second direction Y and the size h11 of the first portions 111 of the first pins 110 in the (i+2)-th row in the second direction Y. Thus the plurality of second pins 210 in the second pin group 200 in the (i+1)-th row are spaced apart from the first fold line L1 of the first pin group 100 in the (i+2)-th row, and the plurality of first pins 110 in the first pin group 100 in the (i+3)-th row are spaced apart from the second fold line L2 in the second pin group 200 in the (i+2)-th row.

The first pin group 100 in the (i+1)-th row may be spaced apart from the first pin group 100 in the (i+3)-th row in the second direction Y, and the second pin group 200 in the i-th row may be spaced apart from of the second pin group 200 in the (i+2)-row in the second direction Y.

In some optional embodiments, the distance d1 between the first pin group 100 in the i-th row and the first pin group 100 in the (i+2)-th row in the second direction Y may be equal to the distance d2 between the second pin group 200 in the (i+1)-th row and the second pin group 200 in the (i+3)-th row in the second direction Y.

Optionally, the distance dl between the first pin group 100 in the i-th row and the first pin group 100 in the (i+2)-th row in the second direction Y is greater than or equal to 50 μm, and the distance d2 between the second pin group 200 in the (i+1)-th row Y from the second pin group 200 in the (i+3)-th row in the second direction is greater than or equal to 50 μm, for convenience of manufacture.

In some optional embodiments, in the pin binding structure provided by the embodiment of the present disclosure, the plurality of first pins 110 and the plurality of second pins 210 respectively in the first pin group 100 and the second pin group 200 that are adjacent may be arranged alternately in sequence in the first direction X.

Optionally, in order to prevent a short-circuit phenomenon during binding, a minimum distance b1 between the first pins 110 and the second pins 210 respectively in the first pin group 100 and the second pin group 200 that are adjacent in the first direction X is greater than or equal to 6 μm.

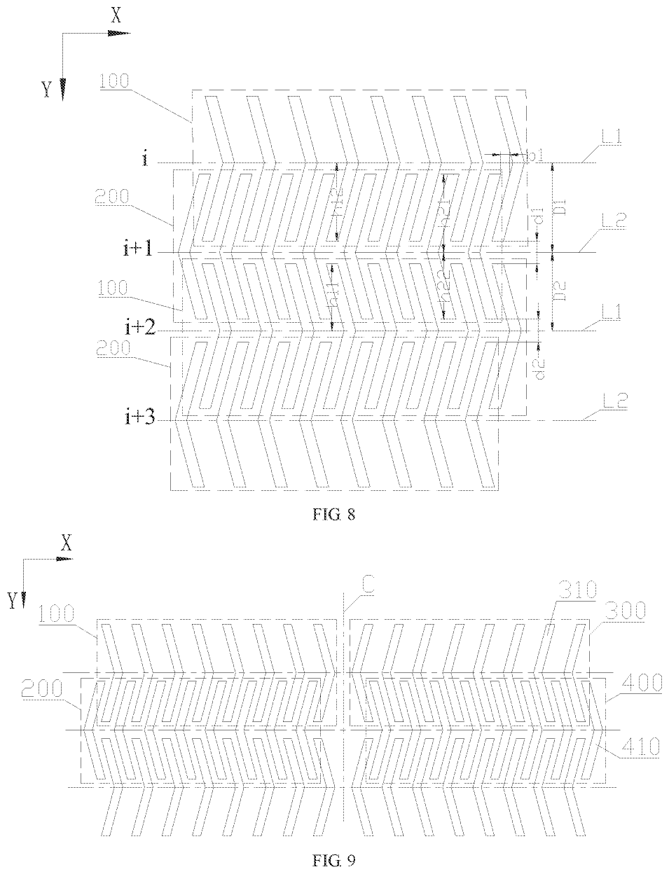

Referring to FIG. 9, the pin binding structure provided by the present disclosure may further include a third pin group 300. The third pin group 300 and the first pin group 100 are alternately distributed along the first direction X. The third pin group 300 includes a plurality of third pins 310 distributed at intervals along the first direction X, and each third pin 310 is in a bent line structure with a third opening. Third openings of the plurality of third pins 310 in the third pin group 300 have the same orientation, and the orientation of the third openings of the third pins 310 is opposite to the orientation of the first openings of the first pins 110.

Optionally, the pin binding structure provided in the present disclosure may further include a fourth pin group 400. The fourth pin group 400 and the second pin group 200 are alternately distributed along the first direction X. The fourth pin group 400 includes a plurality of fourth pins 410 distributed at intervals along the first direction X, and each fourth pin 410 is in a bent line structure with a fourth opening. Fourth openings of the plurality of fourth pins 410 in the fourth pin group 400 have the same orientation, and the orientation of the fourth openings of the fourth pins 410 is opposite to the orientation of the second openings of the second pins 210.

Optionally, the third pin group 300 and the fourth pin group 400 are distributed alternately along the second direction Y, and the plurality of third pins 310 an the plurality of fourth pins 410 respectively in the third pin group 300 and the fourth pin group 400 that are adjacent are at least partially arranged in a comb-tooth-shaped insertion manner.

In the pin binding structure provided by the embodiment of the present disclosure, there is a certain reserved space between the third pin group 300 and the first pin group 100, and a certain reserved space between the fourth pin group 400 and the second pin group 200, which can be used for wiring lines, etc. Specifically, the third pin group 300 and the fourth pin group 400 can be determined to be provided or not according to a shape and size of the binding space, so as to maximize the use of the binding space and arrange more pins in the binding space.

Optionally, in order to facilitate manufacturing the pins, the pin binding structure provided by the present disclosure may have a center line C along the second direction Y. The third pin group 300 and the first pin group 100 may be arranged symmetrically with the center line C as an axis of symmetry. The fourth pin group 400 and the second pin group 200 can be arranged symmetrically with the center line C as an axis of symmetry.

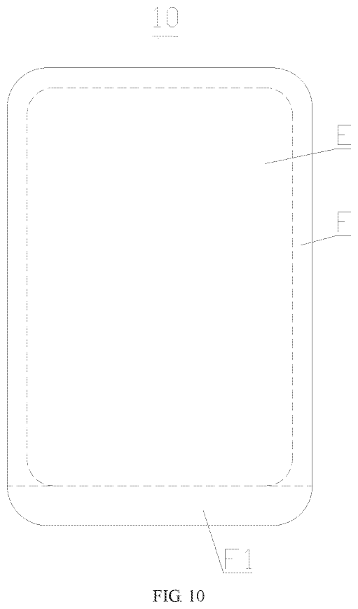

Referring to FIG. 10, an embodiment of the present disclosure also provides an array substrate, including a first area E and a second area F. The second area F is distributed around the first area E. The second area F includes a binding area F1 with a plurality of pins that can adopt the pin binding structure as described above.

The array substrate provided according to the embodiment of the present disclosure adopts the aforementioned pin binding structure, so the arrangement of the pins on the bonding area F1 of the array substrate is more compact and reasonable, and more pins can be arranged, which is able to meet needs of display panels with high refresh rate and high resolution performance.

Furthermore, an embodiment of the present disclosure also provides a display panel, including the aforementioned array substrate.

Those skilled in the art should understand that the above-mentioned embodiments are illustrative rather than restrictive. Different technical features in different embodiments can be combined to achieve beneficial effects. Those skilled in the art should be able to understand and implement other modified embodiments of the disclosed embodiments on the basis of studying the drawings, specification and claims.

What is claimed is:

1. A pin binding structure, comprising:
at least one first pin group, wherein each first pin group comprises a plurality of first pins distributed at intervals along a first direction, each first pin is formed in a bent line structure with a first opening, and first openings of the plurality of first pins in the first pin group have the same orientation;
at least one second pin group, wherein each second pin group comprises a plurality of second pins distributed at intervals along the first direction, each second pin is formed in a bent line structure with a second opening, second openings of the plurality of second pins in the second pin group have the same orientation, and the orientation of the second openings of the second pins is opposite to the orientation of the first openings of the first pins,
wherein the first pin group and the second pin group are distributed along a second direction, and the plurality of first pins and the plurality of second pins respectively in the first pin group and the second pin group that are adjacent are at least partially distributed in a comb-tooth-shaped insertion manner.

2. The pin binding structure according to claim 1, wherein each first pin comprises a first portion and a second portion arranged in sequence in the second direction and connected at a first predetermined angle, and each second pin comprises a first connecting portion and a second connecting portion arranged in sequence in the second direction and connected at a second predetermined angle.

3. The pin binding structure according to claim 2, wherein first connecting portions of the second pins in the second pin group in the (i+1)-th row are parallel to second portions of the first pins in the first pin group in the i-th row, and i is defined as any integer greater than or equal to 1.

4. The pin binding structure according to claim 2, wherein second connecting portions of the second pins in the second pin group in the (i+1)-th row are parallel to first portions of the first pins in the first pin group in the (i+2)-th row.

5. The pin binding structure according to claim 2, wherein a size of first connecting portions of the second pins in the second pin group in the (i+1)-th row is equal to a size of second portions of the first pins in the first pin group in the i-th row; and
a size of second connecting portions of the second pins in the second pin group in the (i+1)-th row is equal to a size of first portions of the first pins in the first pin group in the (i+2)-th row.

6. The pin binding structure according to claim 2, wherein the first portion and the second portion of each first pin are arranged symmetrically in the first direction; and
the first connecting portion and the second connecting portion of each second pin are arranged symmetrically in the first direction.

7. The pin binding structure according to claim 2, wherein the first pin group has a first fold line along the first direction, the first portion and the second portion of each first pin are respectively located on two sides of the first fold line, the second pin group has a second fold line along the first direction, and the first connecting portion and the second connecting portion of each second pin are respectively located on two sides of the second fold line.

8. The pin binding structure according to claim 7, wherein the plurality of first pins of the first pin group in the i-th row are spaced apart from the second fold line of the second pin group in the (i+1)-th row, and the plurality of second pins in the second pin group in the (i+1)-th row are spaced apart from the first fold line of the first pin group in the (i+2)-th row.

9. The pin binding structure according to claim 7, wherein the plurality of second pins in the second pin group in the (i+1)-th row are spaced apart from the first fold line of the first pin group in the (i+2)-th row, and the plurality of first pins in the first pin group in the (i+2)-th row are spaced apart from the second fold line in the second pin group in the (i+1)-th row.

10. The pin binding structure according to claim 7, wherein a distance between the first fold line of the first pin group in the i-th row and the second fold line of the second pin group in the (i+1)-th row is equal to a distance between the second fold line of the second pin group in the (i+1)-th row and the first fold line of the first pin group in the (i+2)-th row.

11. The pin binding structure according to claim 1, wherein the first pin group in the i-th row are spaced apart from the first pin group in the (i+2)-th row in the second direction, and the second pin group in the (i+1)-th row are spaced apart from the second pin group in the (i+3)-th row in the second direction.

12. The pin binding structure according to claim 11, wherein a distance between the first pin group in the i-th row and the first pin group in the (i+2)-th row in the second direction is equal to a distance between the second pin group in the (i+1)-th row and the second pin group in the (i+3)-th row in the second direction.

13. The pin binding structure according to claim 11, wherein a distance between the first pin group in the i-th row and the first pin group in the (i+2)-th row in the second direction is greater than or equal to 50 μm, and a distance between the second pin group in the (i+1)-th row and the second pin group in the (i+3)-th row in the second direction is greater than or equal to 50 μm.

14. The pin binding structure according to claim 1, wherein the plurality of first pins and the plurality of second pins respectively in the first pin group and the second pin group that are adjacent are arranged alternately in sequence in the first direction.

15. The pin binding structure according to claim 14, wherein a minimum distance between the first pins and the second pins respectively in the first pin group and the second pin group that are adjacent in the first direction is greater than or equal to 6 μm; and
a minimum distance between two adjacent first pins in the first pin group in the first direction is greater than or equal to 6 μm; and a minimum distance between two adjacent second pins in the second pin group in the first direction is greater than or equal to 6 μm.

16. The pin binding structure according to claim 1, further comprising:
a third pin group, wherein the third pin group and the first pin group are alternately distributed along the first direction, the third pin group comprises a plurality of third pins distributed at intervals along the first direction, each third pin is formed in a bent line structure with a third opening, third openings of the plurality of third pins in the third pin group have the same orientation, and the orientation of the third openings of the third pins is opposite to the orientation of the first openings of the first pins; and
a fourth pin group, wherein the fourth pin group and the second pin group are alternately distributed along the first direction, the fourth pin group comprises a plurality of fourth pins distributed at intervals along the first direction, each fourth pin is formed in a bent line structure with a fourth opening, fourth openings of the plurality of fourth pins in the fourth pin group have the same orientation, and the orientation of the fourth openings of the four pins is opposite to the orientation of the second openings of the second pins.

17. The pin binding structure according to claim 16, wherein the third pin group and the fourth pin group are alternately distributed along the second direction, and the plurality of third pins and the plurality of fourth pins respectively in the third pin group and the fourth pin group that are adjacent are at least partially arranged in a comb-tooth-shaped insertion manner.

18. The pin binding structure according to claim 16, wherein the pin binding structure has a center line along the second direction, the third pin group and the first pin group are arranged symmetrically with the center line as an axis of symmetry, and the fourth pin group and the second pin group are arranged symmetrically with the center line as an axis of symmetry.

19. An array substrate, comprising a first area and a second area, wherein the second area is distributed around the first area, and the second area comprises a binding area provided with a plurality of pins adopting the pin binding structure according claim 1.

20. A display panel comprising the array substrate according to claim 19.
